(19) United States
(12) Patent Application Publication
(10) Pub. No.: US 2025/0301723 A1
(43) Pub. Date: Sep. 25, 2025

(54) SEMICONDUCTOR DEVICE

(71) Applicant: Sanken Electric Co., Ltd., Saitama-ken (JP)

(72) Inventor: Taro KONDO, Saitama-ken (JP)

(73) Assignee: Sanken Electric Co., Ltd., Saitama-ken (JP)

(21) Appl. No.: 19/021,235

(22) Filed: Jan. 15, 2025

(30) Foreign Application Priority Data
Mar. 21, 2024 (JP) 2024-044849

(51) Int. Cl. H10D 62/10; H10D 12/00; H10D 64/00

(52) U.S. Cl. CPC H10D 62/102; H10D 12/415; H10D 12/481; H10D 62/126; H10D 64/111

(57) ABSTRACT

A semiconductor device includes a semiconductor substrate which includes a first semiconductor region of a first conductivity type and a second semiconductor region of a second conductivity type opposite to the first conductivity type formed on the first semiconductor region, and in which in plan view, an element region in which a semiconductor element is formed and a termination region located closer to an end part side of the semiconductor substrate than the element region are formed. The semiconductor device includes multiple ditch structures formed in parallel in plan view in the termination region, penetrating from a top side through the second semiconductor region and reaching the first semiconductor region, with a conductive layer in a floating state formed inside, and a third semiconductor region of the first conductivity type having higher impurity concentration than the first semiconductor region provided at a bottom of the ditch structure.

### CROSS-REFERENCE TO RELATED APPLICATION

This application claims the priority benefits of Japanese application no. 2024-044849, filed on Mar. 21, 2024. The entirety of the above-mentioned patent application is hereby incorporated by reference herein and made a part of this specification.

### BACKGROUND

### Technical Field

The disclosure relates to a structure of a semiconductor device including a termination region that suppresses a local increase in electric field strength at the termination side of a chip of a power semiconductor element.

### Description of Related Art

To increase the withstand voltage of a switching element, a termination region is provided surrounding the outside of a region (element region) in which the switching element is formed. This termination region is provided with a structure to suppress a local increase in electric field strength.

In cases where a trench-type (where on/off is controlled by the potential of the gate electrode in the trench) IGBT (insulated gate bipolar transistor) or the like is used as the switching element, it is preferable to use a similar trench structure for the structure within the termination region in order to simplify the manufacturing process. Patent Literature 1 (Japanese Patent Application Laid-Open No. 9-283754) and Patent Literature 2 (Japanese Patent No. 5315638) describe semiconductor devices including such termination regions.

FIG. 9 is a cross-sectional view of a part of the element region in a semiconductor device 9, and FIG. 10 is a cross-sectional view of a part of the termination region. In the element region (FIG. 9), a p layer (p-type (second conductivity type) second semiconductor region) 12, which becomes the base region, is formed on a thick n layer (n-type (first conductivity type) first semiconductor region) 11, which becomes the drift layer of the IGBT, in a semiconductor substrate 70. On the surface side of the semiconductor substrate 70, a ditch structure (trench structure) T1 is formed extending in the direction perpendicular to the paper surface along the up-down direction of the paper surface from the surface, penetrating the p layer 12 and reaching the n′ layer 11. An⁺ layer 13, which becomes the emitter region, is locally formed adjacent to both side surfaces of the trench structure T1. Inside the ditch structure T1, a thin oxide film (gate insulating film) 14 is formed, and a gate electrode 21, which is a conductive layer composed of polycrystalline silicon, is formed to fill the ditch structure T1. Additionally, an interlayer insulation layer 16 is locally formed on the upper side of the ditch structure T1 to seal the ditch structure T1 from above. An emitter electrode 22 is formed on the surface of the semiconductor substrate 70, and between the interlayer insulation layers 16, the emitter electrode 22 is electrically connected to the n⁺ layer 13 and the p layer 12, while the emitter electrode 22 is separated from the gate electrode 21.

Furthermore, on the back side (lower side in FIG. 9) of the n⁻ layer 11, a p⁺ layer 17, which becomes the collector layer, is formed, and a collector electrode 23 is formed on the p⁺ layer 17. Additionally, the gate electrodes 21 in all of the ditch structures T1 are connected outside the range shown in the figure, and a control voltage is applied. With this structure, the IGBT operates according to the potentials given to the gate electrode 21, the emitter electrode 22, and the collector electrode 23. Although merely four ditch structures T1 are shown in FIG. 9, in reality, many more ditch structures T1 are formed in parallel in a similar manner.

The structure of the termination region shown in FIG. 10 is actually provided outside the element region shown in FIG. 9. In FIG. 10 as well, the common semiconductor substrate 70 is used, and similarly, the n⁻˜ layer (n-type first semiconductor region) 11, the p layer 12, etc. are provided, and multiple ditch structures T2 are formed in parallel. Here, the common p layer 12 is provided in both the element region and the termination region, but in reality, the impurity concentration etc. of the p layer 12 may differ between the element region and the termination region. Inside the ditch structure T2, the oxide film 14 is formed similarly to the element region, and a conductive layer composed of polycrystalline silicon, similar to the aforementioned gate electrode 21, is also formed similarly. However, the conductive layer formed here is insulated from the surroundings, not electrically connected to the gate electrode 21, and is made into a suspected gate electrode 31 (floating state conductive layer) that is electrically independent for each of the ditch structures T2. Additionally, no layer corresponding to the emitter region (n⁺ layer 13) is formed on the side surface of the ditch structure T2. Moreover, in the termination region, unlike the element region, the interlayer insulation layer 16 is formed to cover the upper part of the semiconductor region between the ditch structures T2. Although merely five ditch structures T2 are shown in FIG. 10, in reality, more ditch structures T2 are arranged beyond the left side of the shown range.

Furthermore, on the termination side (right side in FIG. 10) of the ditch structure T2 in the termination region, a termination electrode 32 is connected via a n⁺ layer 18 locally formed on the surface of the n⁻ layer 11.

When a reverse bias is applied between the n⁻ layer 11 and the p layer 12 of the semiconductor device 9, capacitances are generated as schematically shown in FIG. 11 in the structure of FIG. 10. Here, let C1 be the capacitance generated by the expansion of the depletion layer between the p layer 12 and the n⁻ layer 11 directly therebelow, C2 be the capacitance generated by the expansion of the depletion layer between the suspected gate electrode 31 inside the ditch structure T2 and the n-layer 11 below thereof, and C3 and C4 be the capacitances generated by the expansion of the depletion layer between the suspected gate electrode 31 and the p layer 12 on the left side and the right side thereof, respectively. Through the capacitive junctions, the potential at each of points between an element region X and the end part of the semiconductor substrate 70 (termination electrode 32) is distributed by voltage distribution through capacitive connections, suppressing the occurrence of regions in which the electric field (potential gradient) becomes locally large.

Mobile ions may become trapped on the surface of the semiconductor substrate 70 or in the protective film thereabove. Since the potential of the suspected gate electrode 31 is not fixed, the charge of the mobile ions affects the potential of the suspected gate electrode 31, causing a situation where the region of the n⁻ layer 11 in contact with the bottom of the ditch structure T2 inverts to the opposite conductivity type (p-type). If the inverted region connects with the players 12 on both sides in contact with the ditch structure T2, the capacitances C2 and C3 between the suspected gate electrode 31 and the p layer 12 cease to be generated, and good voltage distribution is unable to be achieved.

Therefore, a semiconductor device that can achieve high withstand voltage with high reliability has been anticipated.

### SUMMARY

The disclosure adopts the following configuration.

The disclosure provides a semiconductor device including a semiconductor substrate which includes a first semiconductor region of a first conductivity type and a second semiconductor region of a second conductivity type opposite to the first conductivity type formed on the first semiconductor region, and in which in plan view, an element region in which a semiconductor element is formed and a termination region located closer to an end part side of the semiconductor substrate than the element region are formed. The semiconductor device includes multiple ditch structures formed in parallel in plan view in the termination region, penetrating from a top side through the second semiconductor region and reaching the first semiconductor region, with a conductive layer in a floating state formed inside, and a third semiconductor region of the first conductivity type having higher impurity concentration than the first semiconductor region that is provided at a bottom of the ditch structure in the semiconductor substrate.

In plan view, the third semiconductor region may be formed in an annular shape surrounding the element region.

The third semiconductor region may not be provided at the bottom of the ditch structure located on the end part side among the ditch structures.

The third semiconductor region may not be provided at the bottom of the ditch structure located on the element region side among the ditch structures.

The disclosure provides a semiconductor device including a semiconductor substrate which includes a first semiconductor region of a first conductivity type and a second semiconductor region of a second conductivity type opposite to the first conductivity type formed on the first semiconductor region, and in which in plan view, an element region in which a semiconductor element is formed and a termination region located closer to an end part side of the semiconductor substrate than the element region are formed. The semiconductor device includes multiple ditch structures formed in parallel in plan view in the termination region, penetrating from a top side through the second semiconductor region and reaching the first semiconductor region, with a conductive layer in a floating state formed inside, and a shallow junction region that is provided in which a depth of the second semiconductor region between the ditch structures provided adjacent to each other between the element region side and the end part side is formed shallower than a depth of the second semiconductor region between the ditch structures provided adjacent to each other on the element region side and the second semiconductor region between the ditch structures provided adjacent to each other on the end part side.

The shallow junction region may be formed between at least three or more adjacent ones of the ditch structures.

In plan view, the shallow junction region may be formed in an annular shape surrounding the element region.

The semiconductor device may include a termination electrode electrically connected to the first semiconductor region on the end part side of the ditch structures in plan view.

The termination electrode may include a field plate part facing the first semiconductor region via an insulation layer on the element region side, and the field plate part may not extend over the ditch structure on the end part side.

Spacing between two adjacent ones of the ditch structures may be wider on the element region side than on the end part side.

The disclosure is configured as described above, so that a semiconductor device that can achieve high withstand voltage with high reliability can be obtained.

### BRIEF DESCRIPTION OF THE DRAWINGS

FIG. 1 is a cross-sectional view showing the structure of a semiconductor device according to a first embodiment of the disclosure.

FIG. 2 is a simplified view showing a part of the planar structure of the semiconductor device according to the first embodiment of the disclosure.

FIG. 3 shows the results of calculating the potential distribution in the first semiconductor region for a conventional semiconductor device and the semiconductor device according to the embodiment.

FIG. 4 is a cross-sectional view showing the structure of a semiconductor device according to a second embodiment of the disclosure.

FIG. 5 is a cross-sectional view showing the structure of a semiconductor device according to a third embodiment of the disclosure.

FIG. 6 is a cross-sectional view showing the structure of a semiconductor device according to a fourth embodiment of the disclosure.

FIG. 7 is a cross-sectional view showing the structure of a semiconductor device according to a fifth embodiment of the disclosure.

FIGS. 8A to 8D show the results of calculating the potential distribution and the shape of the depletion layer in the first semiconductor region in the semiconductor device according to the fifth embodiment of the disclosure, in response to the position of the termination electrode and the presence or absence of trapped charge.

FIG. 9 is a cross-sectional view showing a part of the structure of the element region in a conventional semiconductor device.

FIG. 10 is a cross-sectional view showing a part of the structure of the termination region in a conventional semiconductor device.

FIG. 11 is a schematic diagram showing the capacitive component of the depletion layer occurring in the termination region of a conventional semiconductor device.

### DESCRIPTION OF THE EMBODIMENTS

The following describes a semiconductor device as an embodiment of the disclosure. In the following drawings, the same or similar parts are denoted by the same or similar reference numerals. However, it should be noted that the drawings are schematic and the relationship between thickness and planar dimensions, as well as the ratios of lengths of each of the parts, differ from reality. Therefore, specific dimensions should be determined in consideration of the following description. Of course, there are also parts where the dimensional relationships and ratios differ between the drawings. Furthermore, the embodiments shown below are examples of devices that embody the technical concept of the disclosure, and the technical concept of the disclosure does not specify the shape, structure, arrangement, etc. of the component parts to those described below. The embodiments of the disclosure can be modified in various ways within the scope of the claims. In the disclosure, terms specifying up and down, such as “upper” and “lower”, are used for convenience of description, and even if provided on a side surface, if they are substantially identical to the constituent elements of the disclosure, they fall within the scope of rights of the disclosure. Also, “upper” includes not only cases where it is formed in contact with the object but also cases where it is formed through another layer. In addition, in the disclosure, “connection” is not limited to direct connection, and even if connected through something such as a resistor, if it is substantially identical to the constituent elements of the disclosure, it falls within the scope of rights of this disclosure.

The semiconductor device includes a termination region having the ditch structure T2 etc., similar to the semiconductor device 9 described earlier. However, in this case, the electrical connection between the p layers 12, which should originally be separated, is suppressed the electrical connection between the p layers 12. As a result, higher withstand voltage can be achieved more reliably than in the conventional technology.

### First Embodiment

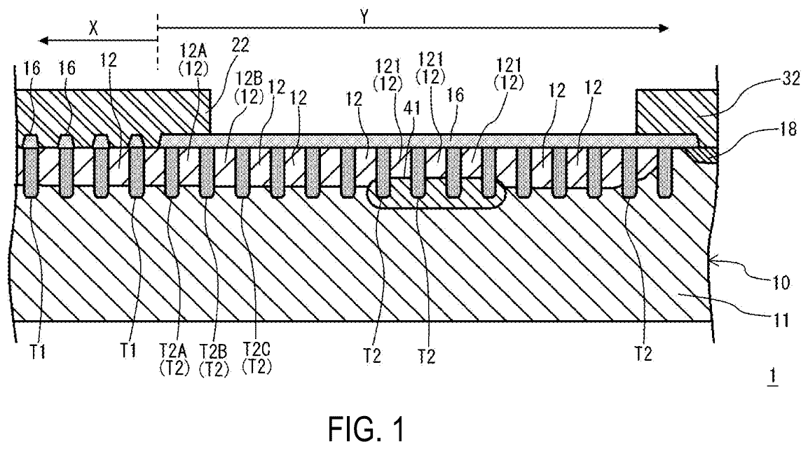

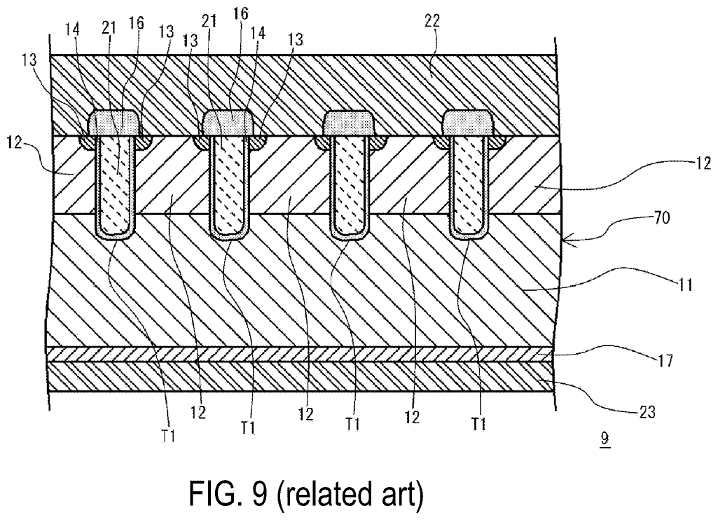

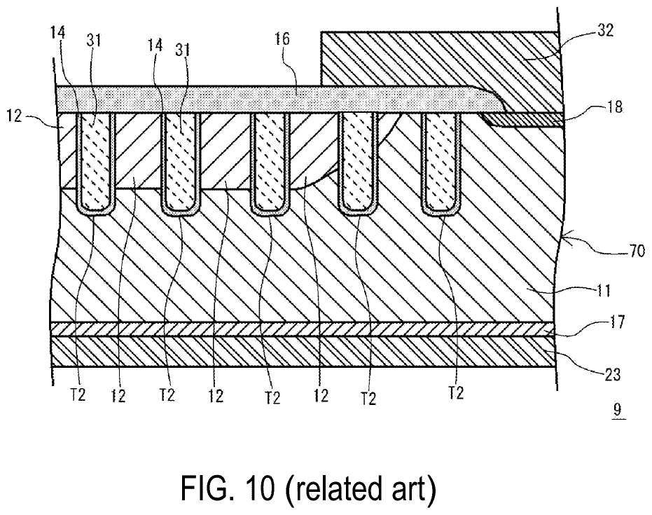

FIG. 1 shows a semiconductor device 1 according to a first embodiment. The left side in FIG. 1 corresponds to the element region X (FIG. 9), and the right side corresponds to a termination region Y (FIG. 10). Here, the description is simplified, and the internal structures (oxide film 14, gate electrode 21, and suspected gate electrode 31) of the n⁺ layer 13 and each of the ditch structures T1 and T2 in FIG. 9 and FIG. 10, as well as the configuration below the n⁻ layer 11, are omitted. Also, the structure in the element region X is the same as in the conventional technology (FIG. 9).

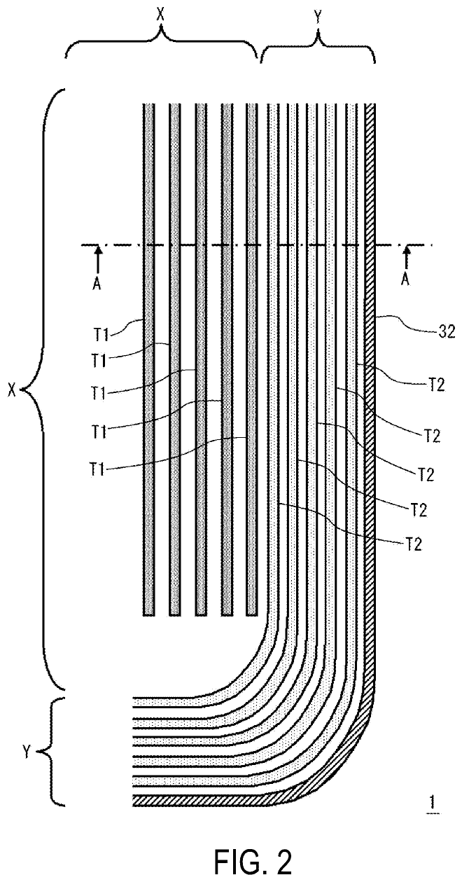

FIG. 2 is a simplified plan view showing the planar structure of the ditch structures T1 and T2, and the termination electrode 32 in the semiconductor device 1. Here, merely five each of the ditch structures T1 and T2 are shown as being provided. In plan view, the semiconductor device 1 (chip) is generally rectangular in shape as a whole, but merely the configuration around one of vertices (the lower right vertex) thereof is shown here, with the center of the chip located to the upper left side of FIG. 2. The configurations around the other three vertices are similar to the form in FIG. 2, with the ditch structure T1 extending in the up-down direction of the paper surface, and the ditch structure T2 and termination electrode 32 rotated by 90° each.

FIG. 1 shows the cross-section along the A-A direction in FIG. 2. As shown in FIG. 2, the ditch structure T2 and the termination electrode 32 (termination region Y) are formed in an annular shape surrounding the periphery of all of the ditch structures T1 (element region X).

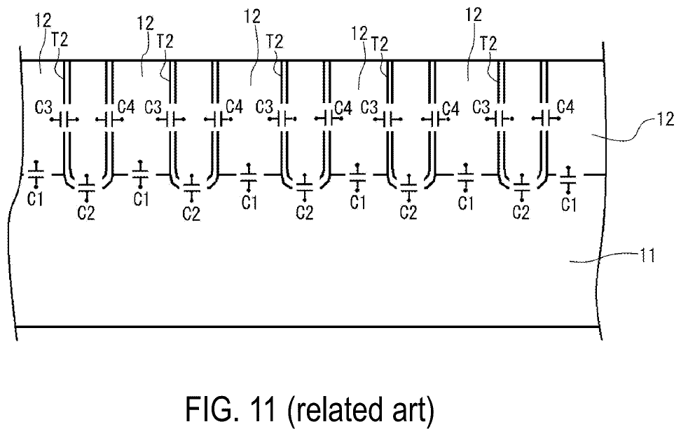

As shown in FIG. 2, since the ditch structure T2 is formed in a closed annular shape, the p layer 12 shown in FIG. 1 is divided by the ditch structure T2. For example, a p layer 12A between the leftmost ditch structure T2A and a ditch structure T2B to the right thereof in the termination region Y in FIG. 1, and a p layer 12B between the ditch structure T2B and a ditch structure T2C to the right thereof are separated from each other. Therefore, unless an inversion layer is formed directly below the ditch structure T2, the capacitances shown in FIG. 11 are formed.

The structure in the termination region Y of the semiconductor substrate 10 used here differs from the structure of the aforementioned semiconductor device 70. In FIG. 1, a n layer (third semiconductor region) 41 with higher impurity concentration than the n⁻ layer 11 is formed between the n⁻ layer 11 and the p layer 12 near the bottom of the four ditch structures T2 on the central side in the termination region Y, and the p layer 12 above the n layer 41 becomes a shallow junction p layer 121. Here, while the impurity concentration of the n layer 11 is set to, for example, 2×10¹⁵ cm⁻³, the impurity concentration of the n layer 41 is set to, for example, 2×10¹⁶ cm⁻³. As a result, the part where the ditch structure T2 contacts at the bottom side becomes the high impurity concentration n layer 41, making it difficult for an inversion layer to occur at the bottom side of the ditch structure T2. This suppresses the electrical connection between the players 121 on both sides of the ditch structure T2 due to the inversion layer as mentioned above, allowing for good potential distribution.

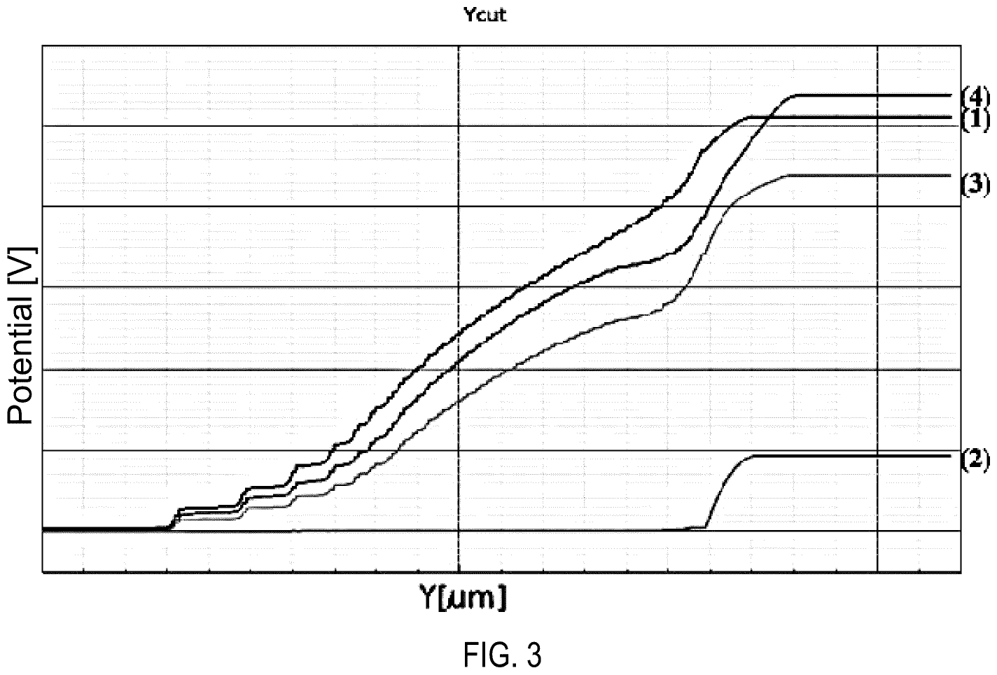

FIG. 3 shows the results of calculating, by simulation, the potential distribution of the n-type layer (first semiconductor region or third semiconductor region) in the termination region at a depth near the bottom of the ditch structure T2 for both the conventional semiconductor device 9 without the n layer 41 and a semiconductor device (including the embodiment described later) with the n layer 41. Here, the lateral axis indicates position, with the left side being the element region (emitter electrode 22) side and the right side being the end part (termination electrode 32) side. The longitudinal axis indicates potential.

In FIG. 3, (1) shows the simulation result for the conventional semiconductor device 9 in the case where there is no trapped charge (ideal case), and (2) shows the simulation result in the case where there is trapped charge. Here, the saturation value (maximum value) of the potential on the right side corresponds to the withstand voltage. In (1), high withstand voltage is obtained by the potential being distributed almost evenly in the termination region, whereas in (2), an inversion layer occurs at the bottom of adjacent ditch structures T2, and the p layers 12 on both sides of the ditch structure T2 are electrically connected, causing the potential to remain almost constant across the ditch structures T2. As a result, the potential rises sharply near the p layer 12 on the end part (termination electrode 32) side, thereby lowering the withstand voltage.

In contrast, (3) shows the simulation result for the semiconductor device 1 with the structure shown in FIG. 1 in the case where there is trapped charge. The result is close to the results of (1), and the withstand voltage is significantly improved compared to (2). In other words, even with trapped charge, high withstand voltage is obtained by the potential being distributed almost evenly in the termination region Y. Thus, the effectiveness of the above-mentioned configuration can be confirmed.

In FIG. 1, it is preferable not to include the n layer 41 on the element region X side of the termination region Y. The potential difference between the n⁻ layer 11 and the suspected gate electrode 31 becomes relatively large on the element region X side of the termination region Y. However, by not including the n layer 41 on the element region X side of the termination region Y, the depletion layer that occurs between the n⁻ layer 11 and the suspected gate electrode 31 can be further expanded.

In addition, it is preferable not to include the n layer 41 on the termination electrode 32 side of the termination region Y. This is because the termination electrode 32 side of the termination region Y is prone to breakdown, and if the n layer (third semiconductor region) 41 is included, the depletion layer that occurs between the n⁻ layer 11 and the suspected gate electrode 31 in the ditch structure T2 in contact with the n layer 41 becomes less likely to expand, making breakdown more likely to occur.

Furthermore, to suppress the coupling of p layers 121 with each other by the inversion layer as described above, it is particularly preferable to form the n layer (third semiconductor region) 41 in an annular shape when viewed planarly, corresponding to the ditch structure T2 in FIG. 2. However, in the case where the formation of such an inversion layer is particularly likely to occur locally due to the structure on the top side other than the structure of the semiconductor device 1 described above, the n layer 41 may be formed locally merely in the region. In other words, unlike the ditch structure T2, the n layer 41 does not certainly need to be formed in a closed annular shape, and may be formed to be locally scattered in the circumferential direction.

The position, size (height, width, thickness, etc.), impurity concentration etc. of the n layer 41 are appropriately provided along with other layers in response to the characteristics required for the semiconductor device 1. The n layer 41 may also be formed separately on the relatively element region X side of the termination region Y and on the relatively termination electrode 32 side of the termination region Y. In FIG. 1, the number of ditch structures T2 with the n layer 41 provided at the bottom is four, but the number may be more or less. The n layer 41 can be appropriately formed, for example, by performing ion implantation etc. towards the bottom of the ditch after dry etching to form the ditches of the ditch structures T1 and T2. The same applies to other embodiments described below.

In the structure of FIG. 1, if all of the ditch structures T2 have the same structure and the spacing between the ditch structures T2 is uniform, the potential gradient (electric field strength) becomes almost uniform as in the case without trapped charge in FIG. 3. In this case, if the spacing is widened on the element region X side, for example, the electric field particularly on the element region X side may be weakened and the electric field concentration may be suppressed in the part. As described in Patent Literature 2, since suppressing the electric field concentration on the element region X side is particularly effective for improving withstand voltage, it is preferable from the viewpoint of improving withstand voltage to make the spacing of the ditch structures T2 wider on the element region X side and narrower on the end part side. On the other hand, keeping the spacing uniform without widening the spacing on the element region X side is effective in miniaturizing the semiconductor device 1. The above matters apply similarly to other embodiments described below.

It is preferable to gradually widen the spacing of the ditch structures T2 towards the element region X side from the ditch structures T2 with the n layer 41 provided at the bottom, and to make the spacing of the ditch structures T2 with the n layer 41 provided at the bottom equal. Furthermore, it is preferable to make the spacing of the ditch structures T2 on the termination electrode 32 side of the ditch structures T2 with the n layer 41 provided at the bottom also equal. This allows for miniaturization of the semiconductor device 1 and achieving high withstand voltage with high reliability.

### Second Embodiment

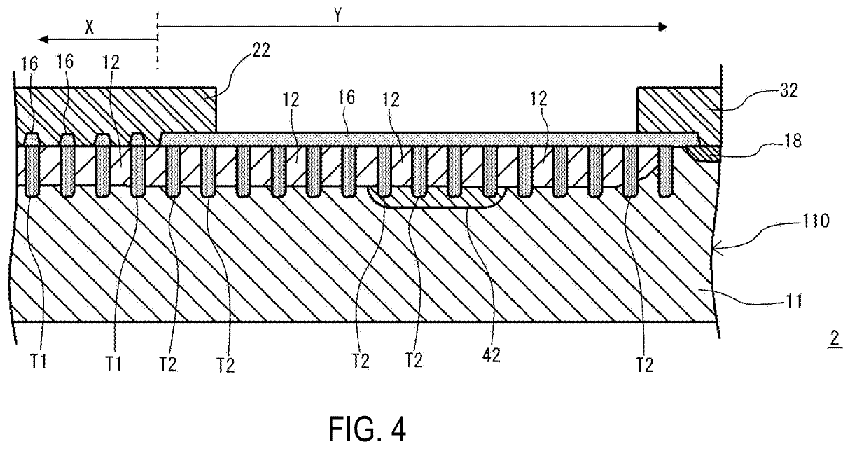

FIG. 4 is a cross-sectional view corresponding to FIG. 1 of a semiconductor device 2 according to a second embodiment. In a semiconductor substrate 110 used in this case, a n layer (third semiconductor region) 42 with the impurity concentration similar to the aforementioned n layer 41 is formed, but the n layer 42 is formed merely on the n⁻ layer 11 side. Unlike the structure in FIG. 1, no part where the p layer 12 becomes locally shallow (shallow junction p layer 121) is formed by the formation of the n layer 42. The bottom of the ditch structure T2 is prone to breakdown, and the closer (deeper) the depth of the p layer 12 on the ditch structure T2 side is to the depth of the bottom of the ditch structure T2, the less likely breakdown is to occur. Therefore, from such a perspective, the withstand voltage of the semiconductor device 2 can be increased.

In this case as well, it is clear that the formation of an inversion layer on the bottom side of the ditch structure T2 is suppressed, similar to the aforementioned semiconductor device 1.

### Third Embodiment

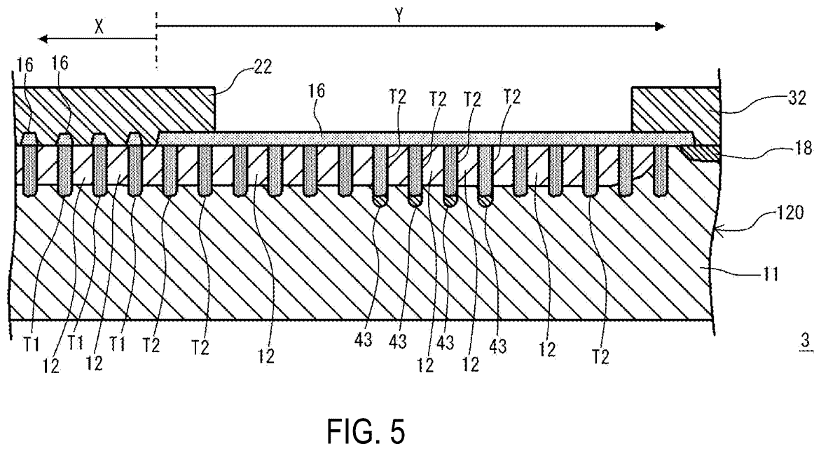

FIG. 5 is a cross-sectional view corresponding to FIG. 1 of a semiconductor device 3 according to a third embodiment. In a semiconductor substrate 120 used in this case, a n layer (third semiconductor region) 43 with the impurity concentration similar to the aforementioned n layer 41 is formed, but the n layer 43 is formed even more locally than the aforementioned n layer 42, merely at the bottom of each of the ditch structures T2. Therefore, in this case, no n layer connecting the bottoms of the ditch structures T2 is formed. It should be noted that parts of the adjacent n layers 43 may be connected to each other, and when viewed in plan view of the termination region Y, parts of the n layer 41 of FIG. 1 or the n layer 42 of FIG. 4 and parts of the n layer 43 of FIG. 5 may coexist.

In this case as well, it is clear that the formation of an inversion layer on the bottom side of the ditch structure T2 is suppressed, similar to the aforementioned semiconductor device 1.

### Fourth Embodiment

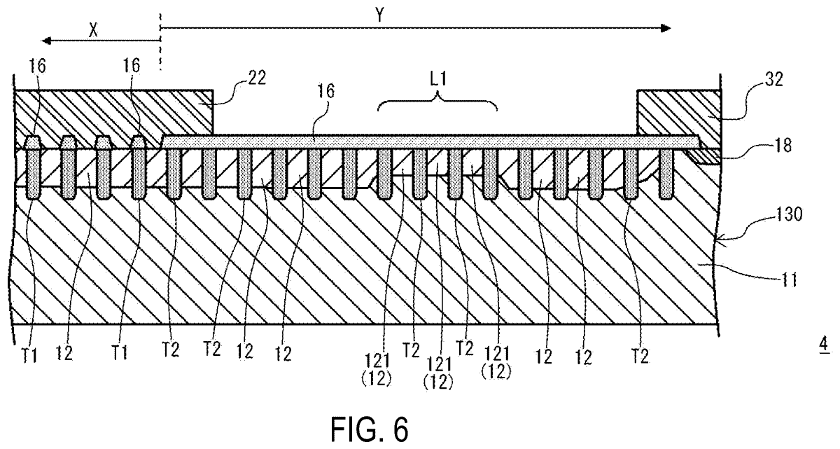

The conduction between the players 12 adjacent to the ditch structure T2 can also be suppressed by lengthening the conduction path between the p layers 12 adjacent to the ditch structure T2, which is caused by the inversion of the n layer in contact with the bottom of the ditch structure T2. FIG. 6 is a cross-sectional view corresponding to FIG. 1 of a semiconductor device 4 according to a fourth embodiment. In the termination region Y of a semiconductor substrate 130, instead of forming the n layer 41 as in the aforementioned semiconductor device 1, the p layer 12 and the shallow junction p layer 121 shallower than the p layer 12 are formed. In FIG. 4, the location where the shallow junction p layer 121 is provided is indicated by a shallow junction region L1. This lengthens the path from one shallow junction p layer 121 adjacent to the ditch structure T2 to the other shallow junction p layer 121, thereby suppressing the conduction between the shallow junction p layers 121 on both sides of the ditch structure T2 due to the inversion layer. It should be noted that the area between the adjacent ditch structures T2 does not certainly need to be the shallow junction p layer 121; if the area between the ditch structures T2 is the shallow junction p layer 121, the area between the adjacent ditch structures T2 may be the p layer 12, or the shallow junction p layers 121 and the p layers 12 may be alternately provided.

Similar to the aforementioned n layer (third semiconductor region), the shallow junction region L1 does not need to be formed in an annular shape in plan view, but may be formed locally in the circumferential direction; the shallow junction region L1 may be provided on the inner or outer side of the termination region Y; and the shallow junction region L1 may be formed separately on the element region X side and the termination electrode 32 side in the termination region Y.

The player 12, a part of which is made into the shallow junction p layer 121, can be formed, for example, by changing the energy of the ion implantation used to form the layer. The structures of the semiconductor devices according to the first to fourth embodiments may be combined with each other.

### Fifth Embodiment

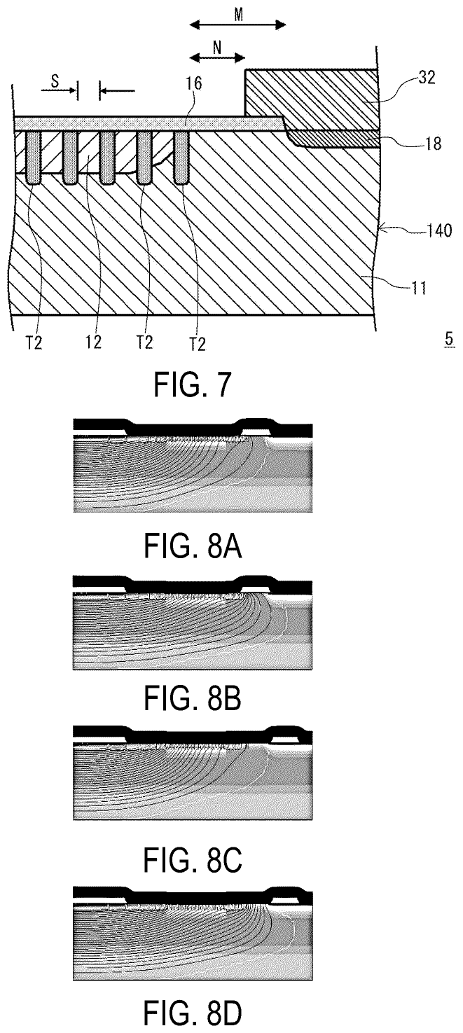

FIG. 7 shows a semiconductor device 5 according to a fifth embodiment. Here, the structure of the termination region Y, particularly on the end part side (near the termination electrode 32), is described. Compared to the structures of the first to fourth embodiments, in a semiconductor substrate 140, spacing M between the location where the termination electrode 32 contacts the n-layer 11 (or the n⁺ layer 18) and the end part of the p layer 12 is larger.

By extending the termination electrode 32 towards the p layer 12 side on the interlayer insulation layer 16, a part of the termination electrode 32 is made to function as a field plate. However, the part functioning as the field plate (field plate part), which is a part of the termination electrode 32, does not extend to an area above the outermost (right side of the figure) ditch structure T2. For example, a distance N from the part functioning as the field plate to the area above the ditch structure T2 is wider than spacing S between the adjacent ditch structures T2.

FIGS. 8A and 8B show the results of calculating, by simulation, equipotential lines (black lines) and depletion layers (white lines) in the n⁻ layer 11 in the case where the field plate part of the termination electrode 32 extends over the ditch structure T2 on the left side thereof (N<0) in the structure of FIG. 7, for the states without trapped charge FIG. 8A and with trapped charge FIG. 8B. Similarly, FIGS. 8C and 8D show the results for the structure of FIG. 7 (N>0) in the states without trapped charge FIG. 8C and with trapped charge FIG. 8D.

In FIGS. 8C and 8D where the field plate part (termination electrode 32) is separated from the ditch structure T2 at the end part, the equipotential lines at the semiconductor surface on the outermost p layer 12 side are more gradual compared to FIGS. 8A and 8B.

(4) in FIG. 3 shows the potential distribution in the semiconductor device 5 in the case where trapped charge exists. Here, the ditch structure T2 and the surrounding structure thereof are the same as in the first embodiment. In this case, in addition to the potential being equally distributed as in (3), due to the above-mentioned effect, the highest withstand voltage among (1) to (4) is obtained.

In the above example, an IGBT is formed in the element region X, but the element formed in the element region X may be arbitrary, such as a diode or a MOSFET. However, it is particularly preferable that the element is also formed using a trench structure (ditch structure) similar to the aforementioned IGBT, as this can simplify the manufacturing process. Additionally, other layers can be added to the semiconductor substrate as appropriate. It is also clear that a similar configuration can be applied in the case where all p-type and n-type in the semiconductor substrate are reversed in the above example.

What is claimed is:

1. A semiconductor device comprising a semiconductor substrate which comprises a first semiconductor region of a first conductivity type and a second semiconductor region of a second conductivity type opposite to the first conductivity type formed on the first semiconductor region, and in which in plan view, an element region in which a semiconductor element is formed and a termination region located closer to an end part side of the semiconductor substrate than the element region are formed, the semiconductor device comprising:
in the termination region,
a plurality of ditch structures formed in parallel in plan view, penetrating from a top side through the second semiconductor region and reaching the first semiconductor region, with a conductive layer in a floating state formed inside; and
a third semiconductor region of the first conductivity type having higher impurity concentration than the first semiconductor region, provided at a bottom of the ditch structure in the semiconductor substrate.

2. The semiconductor device according to claim 1, wherein in plan view, the third semiconductor region is formed in an annular shape surrounding the element region.

3. The semiconductor device according to claim 1, wherein the third semiconductor region is not provided at the bottom of the ditch structure located on the end part side among the plurality of ditch structures.

4. The semiconductor device according to claim 1, wherein the third semiconductor region is not provided at the bottom of the ditch structure located on the element region side among the plurality of ditch structures.

5. A semiconductor device comprising a semiconductor substrate which comprises a first semiconductor region of a first conductivity type and a second semiconductor region of a second conductivity type opposite to the first conductivity type formed on the first semiconductor region, and in which in plan view, an element region in which a semiconductor element is formed and a termination region located closer to an end part side of the semiconductor substrate than the element region are formed, the semiconductor device comprising:
in the termination region,
a plurality of ditch structures formed in parallel in plan view, penetrating from a top side through the second semiconductor region and reaching the first semiconductor region, with a conductive layer in a floating state formed inside; and
a shallow junction region, provided in which a depth of the second semiconductor region between the ditch structures provided adjacent to each other between the element region side and the end part side is formed shallower than a depth of the second semiconductor region between the ditch structures provided adjacent to each other on the element region side and the second semiconductor region between the ditch structures provided adjacent to each other on the end part side.

6. The semiconductor device according to claim 5, wherein the shallow junction region is formed between at least three or more adjacent ones of the ditch structures.

7. The semiconductor device according to claim 5, wherein in plan view, the shallow junction region is formed in an annular shape surrounding the element region.

8. The semiconductor device according to claim 1, comprising a termination electrode, electrically connected to the first semiconductor region on the end part side of the plurality of ditch structures in plan view.

9. The semiconductor device according to claim 8, wherein the termination electrode comprises a field plate part facing the first semiconductor region via an insulation layer on the element region side, and the field plate part does not extend over the ditch structure on the end part side.

10. The semiconductor device according to claim 1, wherein spacing between two adjacent ones of the ditch structures is wider on the element region side than on the end part side.
